(19) United States
(12) Patent Application Publication
(10) Pub. No.: US 2026/0255914 A1
(43) Pub. Date: Aug. 27, 2026

(54) Charged Particle Beam Apparatus and Sample Processing Method

(71) Applicant: Hitachi High-Tech Corporation, Minato-ku, Tokyo (JP)

(72) Inventors: Satoshi MUTO, Tokyo (JP); Shota TORIKAWA, Tokyo (JP); Akinari MORIKAWA, Tokyo (JP)

(21) Appl. No.: 19/163,717

(22) PCT Filed: May 24, 2023
(86) PCT No.: PCT/JP2023/019379

§ 371 Date: Sep. 9, 2025

(51) Int. Cl. H10P 72/00; H01J 37/244; H01J 37/304; H01J 37/31; H10P 74/20

(52) U.S. Cl. CPC H10P 72/0604; H01J 37/244; H01J 37/304; H01J 37/31; H10P 72/0428; H10P 72/0616; H10P 74/203; H01J 2237/221; H01J 2237/2448; H01J 2237/30466; H01J 2237/3109

(57) ABSTRACT

To provide a technique capable of easily detecting an end point of cutting machining on a sample using an ion beam. A charged particle beam apparatus 100 includes a sample chamber 1, an ion beam barrel 2 configured to emit an ion beam IB, an electron beam barrel 4 configured to emit an electron beam EB1, a stage 6 on which a holder 40 holding a sample 30 is placeable, a probe configured to be in contact with the sample 30 placed on the stage 6, a switch configured to switch whether to electrically connect the stage 6 to a ground potential, and a control device C0 configured to control operations of these components.

### TECHNICAL FIELD

The present invention relates to a charged particle beam apparatus and a sample processing method, and more particularly to a charged particle beam apparatus including a switch capable of switching connection of a ground potential to a stage, and a sample processing method performed using the charged particle beam apparatus.

### BACKGROUND ART

In defect analysis for a semiconductor device, a sample for observation is prepared, and a captured image of a defective portion is acquired using a scanning electron microscope (SEM), a transmission electron microscope (TEM), or the like. In order to prepare the sample for observation, a FIB-SEM apparatus capable of emitting a focused ion beam (FIB) is generally used. Although the sample is subjected to cutting machining to a desired defective portion using an ion beam, a technique of detecting an end point of cutting machining is required.

For example, PTL 1 discloses a method of monitoring a resistance value by bringing a probe into contact with both ends of an interconnect in order to detect an end point of cutting machining on the interconnect in interconnect correction in a semiconductor circuit. When the resistance value is more than a threshold value, the cutting using the ion beam ends.

### CITATION LIST

### Patent Literature

PTL 1: WO2012/090321A

### SUMMARY OF INVENTION

### Technical Problem

In the preparation of the sample for observation using the FIB-SEM apparatus, the end point of the cutting machining is detected while checking a captured image (SEM image) during the cutting machining on the sample using the ion beam. However, with miniaturization of the semiconductor device in recent years, it is difficult to detect an end point due to a slight change in the SEM image.

A main object of the present application is to provide a technique capable of easily detecting an end point of cutting machining on a sample using an ion beam even in a fine semiconductor device. Other technical problems and novel features will become apparent from description of the present description and the accompanying drawings.

### Solution to Problem

An outline of a representative one among embodiments disclosed in the present application will be briefly described as follows.

A charged particle beam apparatus according to one embodiment includes: a sample chamber; an ion beam barrel configured to emit an ion beam and attached to the sample chamber; an electron beam barrel configured to emit an electron beam and attached to the sample chamber; a stage on which a holder holding a sample is placeable and which is provided in the sample chamber; a probe configured to be in contact with the sample placed on the stage and provided in the sample chamber; a switch configured to switch whether to electrically connect the stage to a ground potential; and a control device configured to control operations of the ion beam barrel, the electron beam barrel, the stage, the probe, and the switch.

A sample processing method according to one embodiment includes: (a) a step of placing a holder holding a sample on a stage; (b) a step of, after the step (a), bringing a probe into contact with a predetermined interconnect formed on the sample; (c) a step of, after the step (b), bringing the stage into an electrically floating state; (d) a step of, after the step (c), irradiating the sample with an ion beam to cut a part of the sample; (e) a step of, during the step (d), irradiating the sample with an electron beam and observing an SEM image of the sample; and (f) a step of, during the step (e), determining whether there is a special portion in the SEM image being observed. In the step (f), when there is no special portion in the SEM image being observed, the step (d), the step (e), and the step (f) are repeated, and in the step (f), when there is a special portion in the SEM image being observed, the irradiation with the ion beam is stopped.

A sample processing method according to one embodiment includes: (a) a step of placing a holder holding a sample on a stage; (b) a step of, after the step (a), bringing a probe into contact with a predetermined interconnect formed on the sample; (c) a step of, after the step (b), bringing the stage into an electrically floating state; (d) a step of, after the step (c), irradiating the sample with the ion beam to cut a part of the sample; (e) a step of, during the step (d), irradiating the sample with the electron beam and observing an absorption current image of the sample; and (f) a step of, during the step (e), determining whether there is a special portion in the absorption current image being observed. In the step (f), when there is no special portion in the absorption current image being observed, the step (d), the step (e), and the step (f) are repeated, and in the step (f), when there is a special portion in the absorption current image being observed, the irradiation with the ion beam is stopped.

### Advantageous Effects of Invention

According to one embodiment, it is possible to provide a technique capable of easily detecting an end point of cutting machining on a sample using an ion beam.

### BRIEF DESCRIPTION OF DRAWINGS

FIG. 1 is a schematic diagram showing a charged particle beam apparatus according to Embodiment 1.

FIG. 2 is a schematic diagram illustrating an operation of a ground potential control device according to Embodiment 1.

FIG. 3 is a flowchart of a sample processing method according to Embodiment 1.

FIG. 4 is a perspective view showing a state during cutting machining on a sample according to Embodiment 1.

FIG. 5A is a plan view showing a state during the cutting machining on the sample according to Embodiment 1.

FIG. 5B is an SEM image of the sample at the time in FIG. 5A.

FIG. 5C is a plan view showing a state during the cutting machining on the sample according to Embodiment 1.

FIG. 5D is an SEM image of the sample at the time in FIG. 5C.

FIG. 5E is an SEM image of a sample in which no defect occurs.

FIG. 6A is a plan view showing a state during cutting machining on a sample according to a modification.

FIG. 6B is an absorption current image of the sample at the time in FIG. 6A.

FIG. 6C is a plan view showing a state during cutting machining on a sample according to Embodiment 2.

FIG. 6D is an absorption current image of the sample at the time in FIG. 6C.

FIG. 6E is an absorption current image of a sample in which no defect occurs.

### DESCRIPTION OF EMBODIMENTS

Hereinafter, an embodiment will be described in detail with reference to the drawings. In all the drawings for describing the embodiment, members having the same function are denoted by the same reference numeral, and the repeated description thereof is omitted. In the following embodiment, description of the same or similar parts will not be repeated in principle unless particularly necessary.

An X direction, a Y direction, and a Z direction to be described in the present application intersect one another and are orthogonal to one another. In the present application, the Z direction is described as an up-down direction, a depth direction, a height direction, or a thickness direction of a certain structure. In addition, expressions such as a “plan view” used in the present application mean that a surface formed by the X direction and the Y direction is defined as a “plane” and the “plane” is viewed from the Z direction.

### Embodiment 1

### <Charged Particle Beam Apparatus>

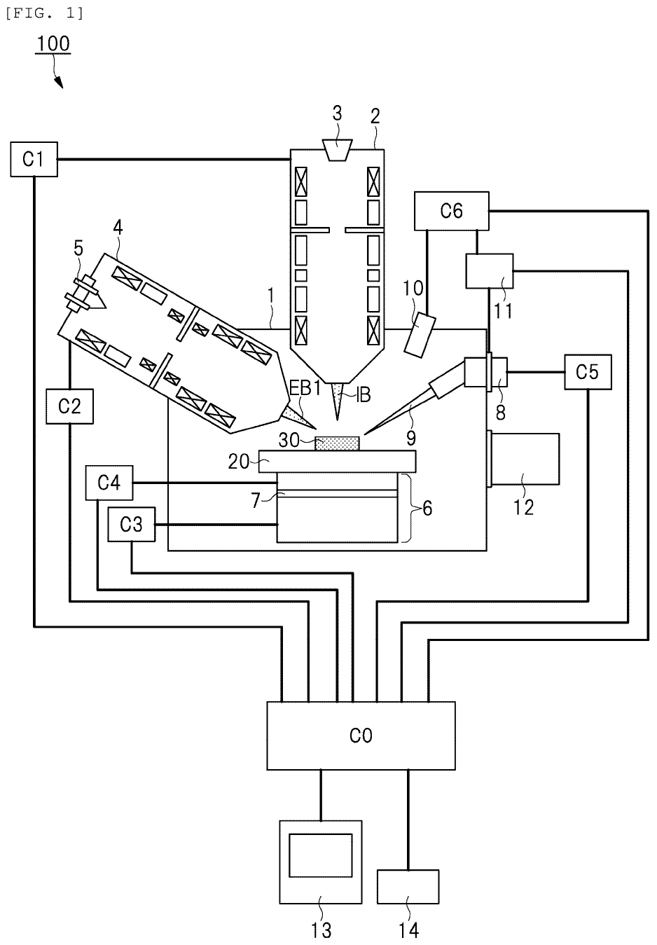

FIG. 1 is a schematic diagram showing a charged particle beam apparatus 100 according to Embodiment 1. The charged particle beam apparatus 100 is, for example, a FIB-SEM apparatus.

As shown in FIG. 1, the charged particle beam apparatus 100 includes a sample chamber 1, an ion beam barrel 2, an electron beam barrel 4, a stage 6, a probe control unit 8, a probe 9, a signal detector 10, a current detector 11, a sample exchange chamber 12, an integrated control device C0, an ion beam control device C1, an electron beam control device C2, a stage control device C3, a ground potential control device C4, a probe control device C5, and an image generation device C6. In addition, a display device 13 and an operation device 14 electrically connected to the integrated control device C0 are provided inside or outside the charged particle beam apparatus 100.

A sample 30 is, for example, a thin piece in which a part of a semiconductor device is formed. The sample 30 includes a semiconductor substrate, a semiconductor element such as a transistor formed on the semiconductor substrate, a plurality of interconnects formed on the semiconductor element, and the like.

The ion beam barrel 2 capable of emitting an ion beam IB is attached to the sample chamber 1. The ion beam barrel 2 includes all components necessary for a FIB apparatus, such as an ion source 3 for generating the ion beam IB, a lens for focusing the ion beam IB, and a deflection system for performing scanning using the ion beam IB and shifting the ion beam IB.

The ion beam control device C1 is electrically connected to the ion beam barrel 2 and controls an operation of the ion beam barrel 2. For example, irradiation with the ion beam IB from the ion source 3, driving of the deflection system, and the like are controlled by the ion beam control device C1.

The electron beam barrel 4 capable of emitting an electron beam EB1 is attached to the sample chamber 1. The electron beam barrel 4 includes all components necessary for an SEM apparatus, such as an electron source 5 for generating the electron beam EB1, a lens for focusing the electron beam EB1, and a deflection system for performing scanning using the electron beam EB1 and shifting the electron beam EB1.

The electron beam control device C2 is electrically connected to the electron beam barrel 4 and controls an operation of the electron beam barrel 4. For example, generation of the electron beam EB1 from the electron source 5, driving of the deflection system, and the like are controlled by the electron beam control device C2.

The stage 6 is provided in the sample chamber 1. An insulator 7 is provided inside the stage 6. A holder 20 holding the sample 30 can be placed on the stage 6. The stage control device C3 is electrically connected to the stage 6 and controls an operation of the stage 6. The holder 20 fixed to the stage 6 can perform a plane movement, a vertical movement, a rotational movement, and an inclined movement by the stage control device C3.

The ground potential control device C4 is electrically connected to the stage 6 and performs an operation of switching connection of a ground potential to the stage 6. The stage 6 and the holder 20 are made of a conductive material. When the stage 6 is connected to the ground potential by the ground potential control device C4, the holder 20 is also connected to the ground potential. The ground potential control device C4 is electrically connected to an upper portion of the stage 6 located above the insulator 7. A lower portion of the stage 6 located under the insulator 7 is always connected to the ground potential. Therefore, the connection of the ground potential can be individually switched only for the upper portion of the stage 6.

The probe 9 and the probe control unit 8 are provided in the sample chamber 1. The probe control unit 8 is connected to the probe 9 and moves the probe 9 in any direction. The probe control device C5 is electrically connected to the probe control unit 8 and controls an operation of the probe 9 via the probe control unit 8. The probe 9 can be brought into contact with the sample 30 placed on the stage 6 by the probe control unit 8.

The signal detector 10 and the current detector 11 are provided in the sample chamber 1. The signal detector 10 can detect a secondary electron or a reflected electron emitted from the sample 30 as a signal EB2 when the sample 30 is irradiated with the electron beam EB1. The current detector 11 can detect a current flowing through the probe 9.

The image generation device C6 is electrically connected to the signal detector 10 and the current detector 11, and controls operations of the signal detector 10 and the current detector 11. The image generation device C6 includes an arithmetic processing circuit that performs arithmetic processing on the signal EB2 detected by the signal detector 10 to generate an image. Therefore, the image generation device C6 can convert the signal EB2 into a captured image (SEM image) of the sample 30. In addition, the image generation device C6 can convert the current detected by the current detector 11 into an absorption current image of the sample 30.

The holder 20 holding the sample 30 is stored in the sample exchange chamber 12. When a sample is to be subjected to cutting machining by irradiation with the ion beam IB, the sample 30 is fixed to the holder 20 and then the holder 20 is transported from the sample exchange chamber 12 into the sample chamber 1.

The operation device 14 is, for example, a device for a user to input instructions such as input of information about the sample 30, change of irradiation conditions of the ion beam IB and the electron beam EB1, and change of positions of the stage 6 and the probe 9. The operation device 14 is, for example, a keyboard or a mouse. A GUI screen or the like is displayed on the display device 13. On the GUI screen, input of various instructions by the operation device 14 can be checked, and the acquired SEM image, absorption current image, and the like can also be checked.

The integrated control device C0 is, for example, an arithmetic processing device including a semiconductor device such as a CPU. The integrated control device C0 is electrically connected to each of the ion beam control device C1, the electron beam control device C2, the stage control device C3, the ground potential control device C4, the probe control device C5, and the image generation device C6, and controls these devices. Therefore, it can also be said that the control performed by each of the devices C1 to C6 is performed by the integrated control device C0. In the present application, for easy understanding of the description, each of the devices C1 to C6 is individually shown near a control target related to each of the devices, but each of the devices C1 to C6 may be integrated into one control unit as a part of the integrated control device C0. Therefore, the integrated control device C0 may be simply referred to as a “control device”.

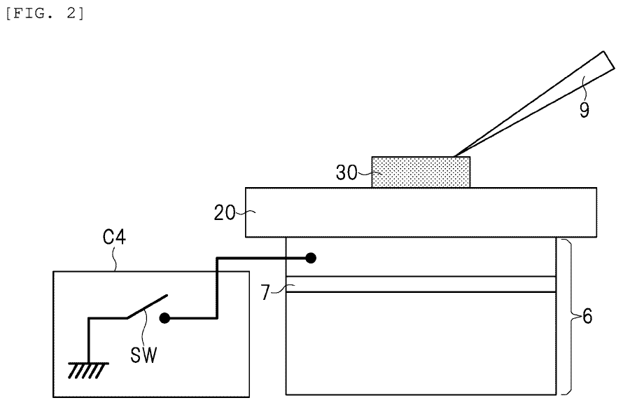

FIG. 2 is a schematic diagram illustrating the operation of the ground potential control device C4. As shown in FIG. 2, the ground potential control device C4 includes a switch SW capable of switching whether to electrically connect the stage 6 to the ground potential.

In a case where the holder 20 holding the sample 30 is placed on the stage 6, when the switch SW is turned on, not only the stage 6 but also the holder 20 and the sample 30 are electrically connected to the ground potential. When the switch SW is turned off, the stage 6, the holder 20, and the sample 30 are electrically floating.

As a main feature of the charged particle beam apparatus 100 according to the present application, an end point of the cutting machining on the sample 30 by irradiation with the ion beam IB is detected in a state where the sample 30 is placed on the stage 6, the probe 9 is in contact with a predetermined interconnect formed on the sample 30, and the stage 6 is electrically floating. In addition, the end point of the cutting machining is detected using the SEM image or the absorption current image of the sample 30 during the cutting machining.

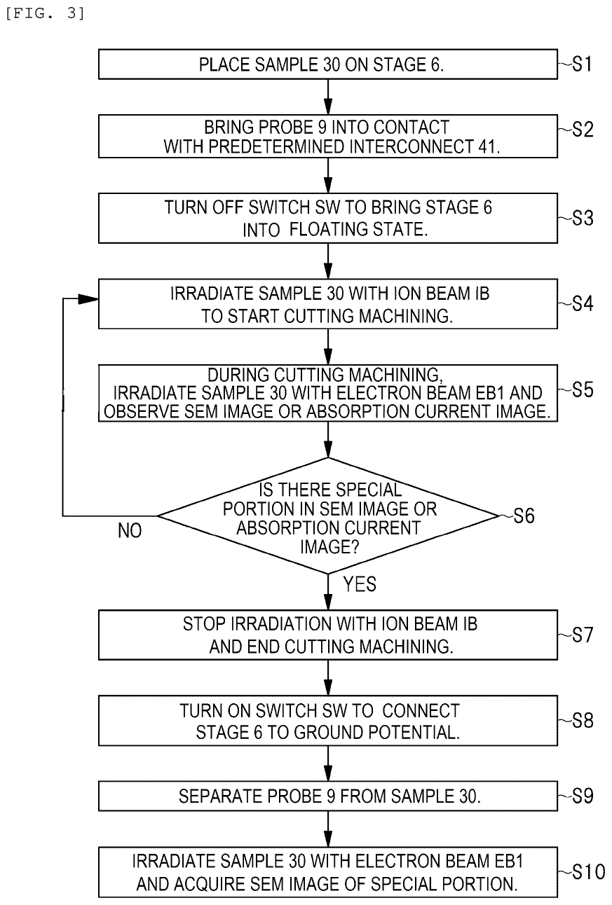

Hereinafter, each step included in a method of processing the sample 30 using the charged particle beam apparatus 100 will be described with reference to FIGS. 3 to 6.

As a premise prior to the method for processing the sample 30, there is a defect in a part of a semiconductor wafer on which the sample 30 is based, and the defective portion is already specified. The sample 30 includes the defective portion, and the sample 30 is subjected to the cutting machining by irradiation with the ion beam IB until the defective portion appears.

### <Sample Processing Method (Case of Using SEM Image)>

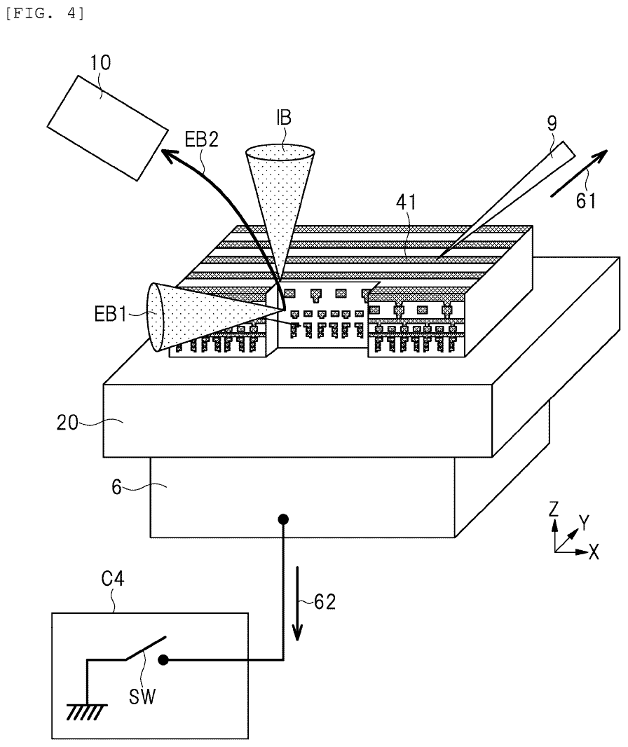

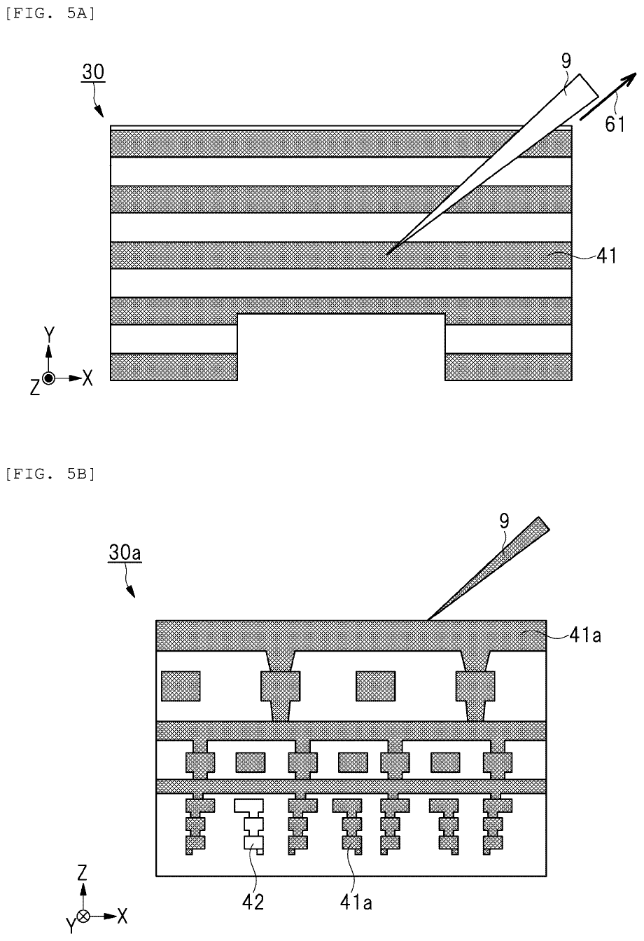

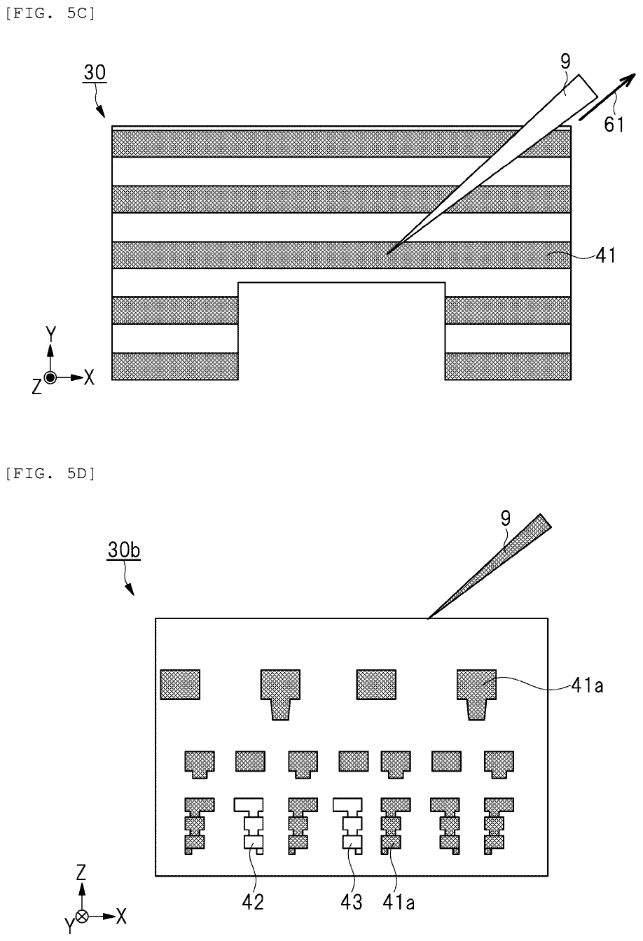

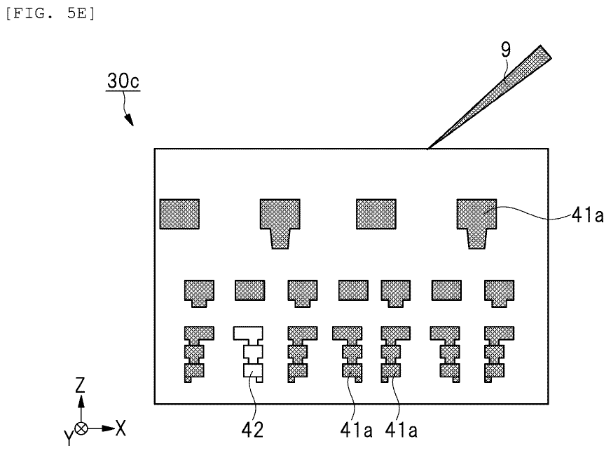

Hereinafter, description will be made mainly along a flowchart in FIG. 3, and FIGS. 4 and 5 are used as necessary. A form of the defective portion of the sample 30 includes a disconnection defect or a short circuit defect. Here, a case where the disconnection defect occurs is exemplified.

In step S1, first, the holder 20 holding the sample 30 is transported from the sample exchange chamber 12 into the sample chamber 1. Next, the holder 20 is placed on the stage 6.

In step S2, as shown in FIG. 4, the probe 9 is brought into contact with a predetermined interconnect 41 formed on the sample 30. The interconnect 41 is an interconnect that is originally electrically connected to a conductor pattern of the defective portion if there is no disconnection defect.

In step S3, the switch SW is turned off to bring the stage 6 into an electrically floating state. Here, a first path 61 on the probe 9 side and a second path on a ground potential side are present paths for charges charged in the interconnect 41, but, as shown in FIG. 4, the charge path in the interconnect 41 is only the first path 61 when the switch SW is turned off.

In step S4, as shown in FIGS. 4 and 5A, the sample 30 is irradiated with the ion beam IB from the ion beam barrel 2 to cut a part of the sample 30.

In step S5, as shown in FIG. 4, the sample 30 is irradiated with the electron beam EB1 from the electron beam barrel 4, and the SEM image of the sample 30 is observed. FIG. 5B shows an SEM image 30a of the sample 30 at the time in FIG. 5A. The sample 30 is charged by being irradiated with the electron beam EB1. However, since the charge path is only the first path 61 on the probe 9 side, a conduction pattern 41a electrically connected to the probe 9 (interconnect 41) is displayed as dark, as shown in FIG. 5B. Here, since a non-conduction pattern 42 that is not electrically connected to the probe 9 (interconnect 41) is electrically floating, the charges are accumulated in the non-conduction pattern 42. Therefore, the non-conduction pattern 42 is displayed as bright, as shown in FIG. 5B.

In step S6, it is determined whether there is a special portion 43 in the SEM image 30a being observed. When there is the special portion 43 (YES), the next step is step S7. When there is no special portion 43 (NO), step S4, step S5, and step S6 are repeated.

The special portion 43 is a portion where a defect occurs in the sample 30, and here, is a portion having a non-conduction pattern due to a disconnection defect. For example, it can be determined that a portion having a contrast largely different from the original contrast, such as a portion that should be displayed as dark but is displayed as bright, is the special portion 43.

FIG. 5C shows a state where the cutting machining on the sample 30 is further advanced than in FIG. 5A. FIG. 5D shows an SEM image 30b of the sample 30 at the time in FIG. 5C. When the special portion 43 appears in the SEM image 30b as shown in FIG. 5D, the process proceeds to step S7, the irradiation with the ion beam IB is stopped, and the cutting machining is ended. That is, the time when the special portion 43 appears is set as the end point of the cutting machining.

An SEM image 30c in FIG. 5E shows the same cross section as the SEM image 30b in FIG. 5D, but is an SEM image of the sample 30 in a case where no disconnection defect occurs. In step S5, a contrast of the SEM image 30b being observed is compared with a contrast of the SEM image 30c, and a portion where these contrasts are different can be determined as the special portion 43.

The determination of the special portion 43 is not limited to the method using the SEM image 30c in the case where no disconnection defect occurs. For example, when there is design data of an internal structure of the sample 30 such as layout data of the semiconductor device including the sample 30, it can be expected that an SEM image of the special portion 43 is originally like the SEM image 30c in FIG. 5E. Therefore, even when the SEM image 30c is not prepared in advance, the end point of the cutting machining can be detected.

After step S7, in step S8, the switch SW is turned on to electrically connect the stage 6 to the ground potential. In step S9, the probe 9 is raised to separate the probe 9 from the sample 30. In step S10, the sample 30 is irradiated with the electron beam EB1 from the electron beam barrel 4, and the SEM image of the sample 30 including the special portion 43 is acquired. That is, the SEM image of a portion where the disconnection defect occurs is acquired.

In this way, according to Embodiment 1, by using a difference in contrast of the SEM images, it is possible to easily detect the end point of the cutting machining on the sample 30 using the ion beam IB even in a fine semiconductor device.

In Embodiment 1, the case where the defect is a disconnection defect is exemplified, but even when the defect is a short circuit defect, the special portion 43 can be determined by the same method. That is, in the case of the disconnection defect, since the special portion 43 is a non-conduction pattern, the special portion 43 is displayed as dark in the SEM image. In the case of the short circuit defect, since the special portion 43 is a conduction pattern, the special portion 43 is displayed as bright in the SEM image.

### Modification

### <Sample Processing Method (Case of Using Absorption Current Image)>

In Embodiment 1, the special portion 43 is determined using the SEM image, but in a modification, a special portion 52 is determined using an absorption current image.

Since steps S1 to S3 shown in FIG. 3 are the same as those in Embodiment 1, and thus description thereof is omitted.

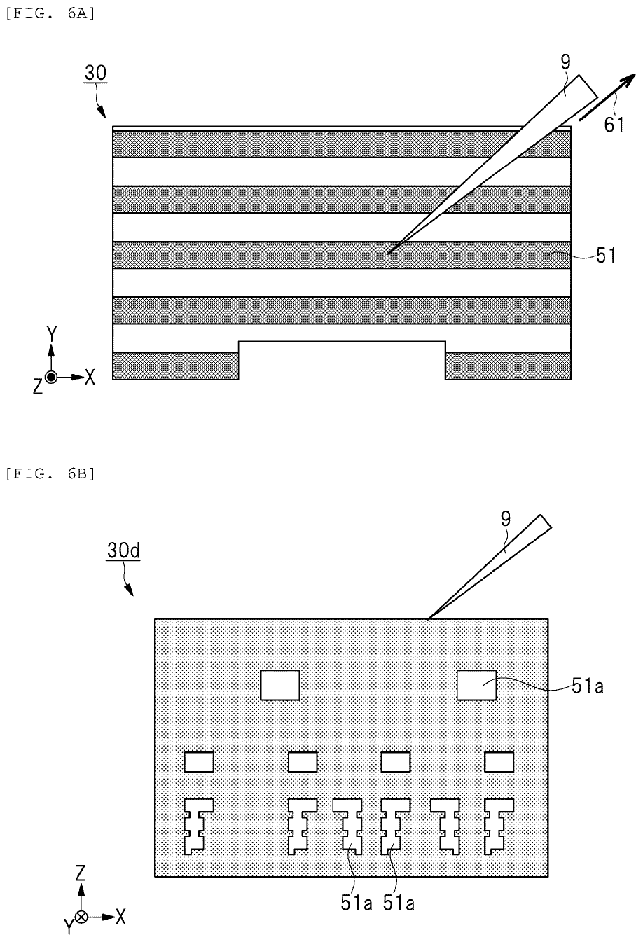

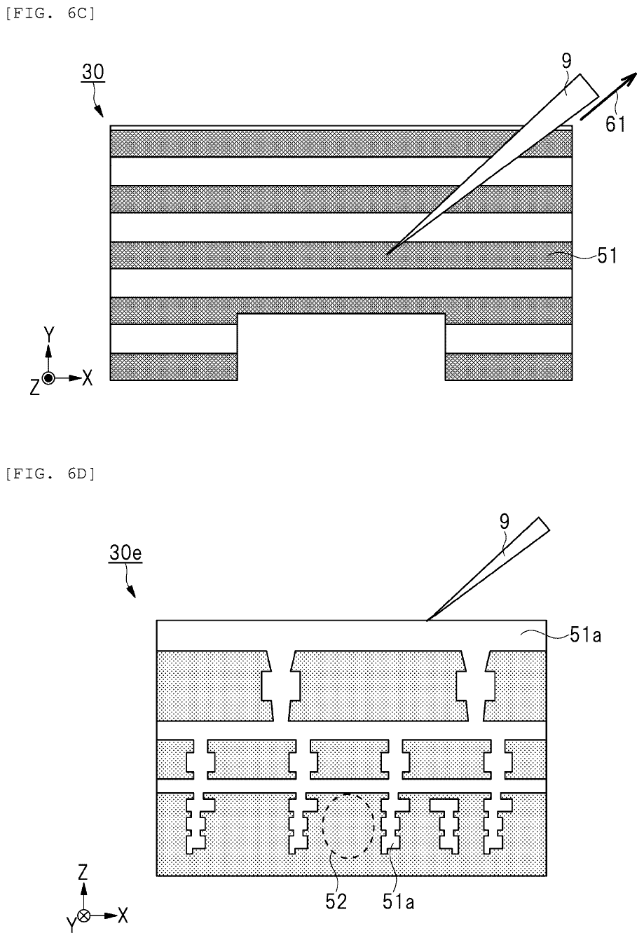

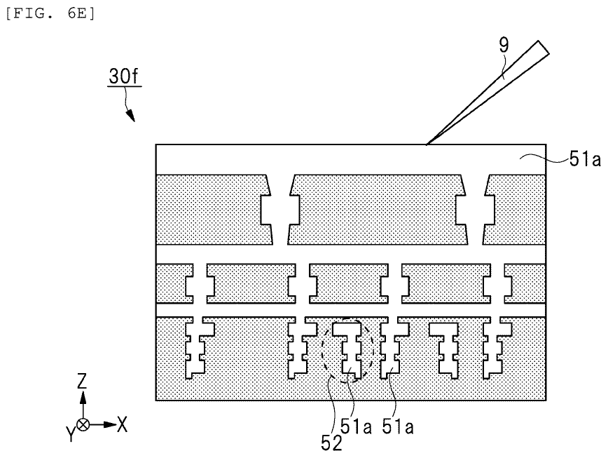

In step S4, as shown in FIG. 6A, the sample 30 is irradiated with the ion beam IB from the ion beam barrel 2 to cut a part of the sample 30. In the modification, a case where the probe 9 is brought into contact with an interconnect 51 formed on the sample 30 is exemplified.

In step S5, the sample 30 is irradiated with the electron beam EB1 from the electron beam barrel 4, and the absorption current image of the sample 30 is observed. FIG. 6B shows an absorption current image 30d of the sample 30 at the time in FIG. 6A. The sample 30 is charged by being irradiated with the electron beam EB1. However, since the charge path is only the first path 61 on the probe 9 side, a conduction pattern 51a electrically connected to the probe 9 (interconnect 51) is displayed as bright, as shown in FIG. 6B. In the absorption current image, only the conduction pattern 51a is displayed as a bright contrast.

In step S6, it is determined whether there is the special portion 52 in the absorption current image 30d being observed. When there is the special portion 52 (YES), the next step is step S7. When there is no special portion 52 (NO), step S4, step S5, and step S6 are repeated.

FIG. 6C shows a state where the cutting machining on the sample 30 is further advanced than in FIG. 6A. FIG. 6D shows an absorption current image 30e of the sample 30 at the time in FIG. 6C. When the special portion 52 appears in the absorption current image 30e as shown in FIG. 6D, the process proceeds to step S7, the irradiation with the ion beam IB is stopped, and the cutting machining is ended. That is, the time when the special portion 52 appears is set as the end point of the cutting machining.

An absorption current image 30f in FIG. 6E shows the same cross section as the absorption current image 30e in FIG. 6D, but is an absorption current image of the sample 30 in a case where no disconnection defect occurs.

When the special portion 52 is a portion where a disconnection defect occurs in the sample 30, the absorption current image 30e being observed in step S5 is compared with the absorption current image 30f, and a portion where a contrast is not displayed only in the absorption current image 30e can be determined as the special portion 52.

On the other hand, when the special portion 52 is a portion where a short circuit defect occurs in the sample 30, the absorption current image being observed in step S5 is compared with an absorption current image of the sample 30 in a case where no short circuit defect occurs, and a portion where a contrast is displayed only in the absorption current image being observed can be determined as the special portion 52.

Thereafter, steps S7 to S10 are performed as in Embodiment 1.

In this way, in the modification, by using a difference in contrast of the absorption current images, it is possible to easily detect the end point of the cutting machining on the sample 30 using the ion beam IB even in a fine semiconductor device, as in Embodiment 1.

Although the invention has been specifically described based on the embodiment described above, the invention is not limited to the embodiment described above, and various modifications can be made without departing from the gist of the invention.

### REFERENCE SIGNS LIST

100: charged particle beam apparatus (FIB-SEM apparatus)
1: sample chamber
2: ion beam barrel
3: ion source
4: electron beam barrel
5: electron source
6: stage
7: insulator
8: probe control unit
9: probe
10: signal detector
11: current detector
12: sample exchange chamber
13: display device
14: operation device
20: holder
30: sample
30a, 30b, 30c: SEM image
30d, 30e, 30f: absorption current image
41: interconnect
41a: conduction pattern
42: non-conduction pattern
43: special portion (non-conduction pattern)
51: interconnect
51a: conduction pattern
52: special portion
61: first path
62: second path
C0: integrated control device (control device)
C1: ion beam control device
C2: electron beam control device
C3: stage control device
C4: ground potential control device
C5: probe control device
C6: image generation device
EB1: electron beam
EB2: signal (secondary electron, reflected electron)
IB: ion beam
SW: switch

1. A charged particle beam apparatus comprising:
a sample chamber;
an ion beam barrel configured to emit an ion beam and attached to the sample chamber;
an electron beam barrel configured to emit an electron beam and attached to the sample chamber;
a stage on which a holder holding a sample is placeable and which is provided in the sample chamber;
a probe configured to be in contact with the sample placed on the stage and provided in the sample chamber;
a switch configured to switch whether to electrically connect the stage to a ground potential; and
a control device configured to control operations of the ion beam barrel, the electron beam barrel, the stage, the probe, and the switch.

2. The charged particle beam apparatus according to claim 1, further comprising:
a signal detector configured to detect, as a signal, a secondary electron or a reflected electron emitted from the sample when the sample is irradiated with the electron beam, the signal detector being provided in the sample chamber; and
an image generation device configured to convert the signal detected by the signal detector into an SEM image of the sample, wherein
the control device is configured to control operations of the signal detector and the image generation device, and
during cutting machining on the sample by irradiation with the ion beam, end point detection of the cutting machining is performable using the SEM image of the sample.

3. The charged particle beam apparatus according to claim 2, wherein
the end point detection of the cutting machining is performed in a state where the sample is placed on the stage, the probe is in contact with a predetermined interconnect formed on the sample, and the stage is electrically floating.

4. The charged particle beam apparatus according to claim 3, wherein
a contrast of an SEM image of the sample during the cutting machining is compared with a contrast of an SEM image of the sample in a case where no disconnection defect or short circuit defect occurs, and a time when a portion where these contrasts are different is detected is set as an end point of the cutting machining.

5. The charged particle beam apparatus according to claim 1, further comprising:
a current detector configured to detect a current flowing through the probe and electrically connected to the probe; and
an image generation device configured to convert the current detected by the current detector into an absorption current image of the sample, wherein
the control device is configured to control operations of the current detector and the image generation device, and
during cutting machining on the sample by irradiation with the ion beam, end point detection of the cutting machining is performable using the absorption current image of the sample.

6. The charged particle beam apparatus according to claim 5, wherein
the end point detection of the cutting machining is performed in a state where the sample is placed on the stage, the probe is in contact with a predetermined interconnect formed on the sample, and the stage is electrically floating.

7. The charged particle beam apparatus according to claim 6, wherein
an absorption current image of the sample during the cutting machining is compared with an absorption current image of the sample in a case where no disconnection defect or short circuit defect occurs, and a time when a portion where a contrast is not displayed only in the absorption current image of the sample during the cutting machining or a time when a portion where a contrast is displayed only in the absorption current image of the sample during the cutting machining is detected is set as an end point of the cutting machining.

8. A sample processing method comprising:
(a) a step of placing a holder holding a sample on a stage;
(b) a step of, after the step (a), bringing a probe into contact with a predetermined interconnect formed on the sample;
(c) a step of, after the step (b), bringing the stage into an electrically floating state;
(d) a step of, after the step (c), irradiating the sample with an ion beam to cut a part of the sample;
(e) a step of, during the step (d), irradiating the sample with an electron beam and observing an SEM image of the sample; and
(f) a step of, during the step (e), determining whether there is a special portion in the SEM image being observed, wherein
in the step (f), when there is no special portion in the SEM image being observed, the step (d), the step (e), and the step (f) are repeated, and
in the step (f), when there is a special portion in the SEM image being observed, the irradiation with the ion beam is stopped.

9. The sample processing method according to claim 8, wherein
the special portion is a portion where a disconnection defect or a short circuit defect occurs in the sample, and
in the step (f), a contrast of the SEM image being observed is compared with a contrast of an SEM image of the sample in a case where no disconnection defect or short circuit defect occurs, and a portion where these contrasts are different is determined as the special portion.

10. The sample processing method according to claim 8, further comprising:
(g) a step of, in the step (f), electrically connecting the stage to a ground potential after the irradiation with the ion beam is stopped;
(h) a step of, after the step (g), separating the probe from the sample; and
(i) a step of, after the step (h), irradiating the sample with the electron beam and acquiring an SEM image of the sample including the special portion.

11. A sample processing method comprising:
(a) a step of placing a holder holding a sample on a stage;
(b) a step of, after the step (a), bringing a probe into contact with a predetermined interconnect formed on the sample;
(c) a step of, after the step (b), bringing the stage into an electrically floating state;
(d) a step of, after the step (c), irradiating an sample with the ion beam to cut a part of the sample;
(e) a step of, during the step (d), irradiating the sample with an electron beam and observing an absorption current image of the sample; and
(f) a step of, during the step (e), determining whether there is a special portion in the absorption current image being observed, wherein
in the step (f), when there is no special portion in the absorption current image being observed, the step (d), the step (e), and the step (f) are repeated, and
in the step (f), when there is a special portion in the absorption current image being observed, the irradiation with the ion beam is stopped.

12. The sample processing method according to claim 11, wherein
the special portion is a portion where a disconnection defect occurs in the sample, and
in the step (f), the absorption current image being observed is compared with an absorption current image of the sample in a case where no disconnection defect occurs, and a portion where a contrast is not displayed only in the absorption current image being observed is determined as the special portion.

13. The sample processing method according to claim 11, wherein
the special portion is a portion where a short circuit defect occurs in the sample, and
in the step (f), the absorption current image being observed is compared with an absorption current image of the sample in a case where no short circuit defect occurs, and a portion where a contrast is displayed only in the absorption current image being observed is determined as the special portion.

14. The sample processing method according to claim 11, further comprising:
(g) a step of, in the step (f), electrically connecting the stage to a ground potential after the irradiation with the ion beam is stopped;
(h) a step of, after the step (g), separating the probe from the sample; and
(i) a step of, after the step (h), irradiating the sample with the electron beam and acquiring an SEM image of the sample including the special portion.
